(19) United States
(12) Patent Application Publication
(10) Pub. No.: US 2016/0016369 A1
(43) Pub. Date: Jan. 21, 2016

(54) Novel Additive Manufacturing-Based Electric Poling Process of PVDF Polymer for Piezoelectric Device Applications

(71) Applicant: University of South Carolina, Columbia, SC (US)

(72) Inventors: Joshua Tarbutton, Columbia, SC (US); Chabum Lee, Columbia, SC (US)

(21) Appl. No.: 14/718,648

(22) Filed: May 21, 2015

Related U.S. Application Data
(60) Provisional application No. 62/001,275, filed on May 21, 2014.

(51) Int. Cl. B29C 71/00; H01L 41/193; H01L 41/333; B29C 67/00

(52) U.S. Cl. CPC B29C 71/0081; B29C 67/0055; B29C 67/0085; H01L 41/193; H01L 41/333; B29K 2027/16

(57) ABSTRACT

Methods for forming a piezoelectric device are provided. The method can comprise: electrically poling and printing the piezoelectric device from a polymeric filament simultaneously. The polymeric filament can comprise a polyvinylidene fluoride polymer (e.g., a β phase polyvinylidene fluoride polymer, such as formed by simultaneously stretching and electric poling an electrically inactive α phase polyvinylidene fluoride polymer).

### PRIORITY INFORMATION

The present application claims priority to U.S. Provisional Patent Application Ser. No. 62/001,275 titled “Novel Additive Manufacturing-Based Electric Poling Process of PVDF Polymer for Piezoelectric Device Applications” of Tarbutton, et al. filed on May 21, 2014; the disclosure of which is incorporated by reference herein.

### BACKGROUND

Piezoelectric devices, combined with the development of piezoelectric materials, have become a key enabling technology for a wide range of industrial and consumer products including actuators and sensors, biomimetics and robotics, energy harvesting and storage devices, etc. The piezoelectric device market experienced robust growth in last two decades, and also sustained fairly healthy growth even during the global economic downturns. It will again witness strong growth in the next years, and certain application markets already enjoy double digit growth.

Piezoelectric ceramics is the largest material group for piezoelectric devices, while piezoelectric polymers demonstrate the fastest growth due to their light weight and small size. Piezoelectric polymers are especially promising for devices with this type of functionality because they can transform deformations induced by small force and pressure, mechanical vibration, elongation/compression, bending or twisting into useful power or information. Such devices can be used for sensing and actuation applications as well as energy harvesting applications.

Piezoelectric polymers (e.g., fluorocarbon based polymer with multiple strong carbon-fluorine bonds) are a specialized group of polymeric materials, which are used in a wide range of applications due to unique properties and distinct performance characteristics. The piezoelectric polymer market presents strong growth driven by the development of new applications and products, advancement of application processes, and new technological developments, as well as strong demands in new markets.

Piezoelectric polymers combine structural flexibility, easy of processing and good chemical resistance with large areas of sensitivity, simplicity in device design and associated potential for low cost implementation. In recent years there has been increasing interest in the piezoelectric behavior of both synthetic and natural polymers. In general, piezoelectric polarization can be produced by application of either tensile or shear stresses. Polyvinylidene fluoride (PVDF) is a widely studied polymer that exists in piezoelectric form with potential applications in various sensing and actuation applications due to its low cost, chemical robustness and favorable mechanical properties. PVDF is a semi-crystalline polymer commercially available as solution, power, granules or semi-transparent film type.

Piezoelectric PVDF polymers are traditionally manufactured by using mechanical stretching, contact poling, corona poling or electro-spinning process in order to allow for dipole alignment of the polymer. Stretching a PVDF material about 4 to about 5 times longer than its nominal length in either a uniaxial or biaxial direction provides molecular chain alignment and transforms the polymer from its α phase which cannot be made piezoelectric, to its β phase which can be made piezoelectric by applying a strong electric field. Applying a strong electric field to β phase PVDF results in dipole alignment along the electric field and is referred as contact poling. Corona poling ionizes air molecules above the material through the use of a corona needle. In order to allow polymer chain to align and reorganize, PVDF polymer is held at high temperature during stretching and poling. Mechanical stretching, contact poling, and corona poling processes are not suitable for a continuous production, but electrospinning is a unique technique able to produce continuous PVDF fibers from PVDF solutions in the presence of an electrical field.

Many researchers have studied various aspects of the development of new piezoelectric polymer materials, their processing processes and application device design in both industry and academia. However, current PVDF processing technologies cannot produce realistic piezoelectric devices with large sensitive area and high degrees of alignment and uniformity in a continuous fabrication process. Thus, a tremendous knowledge gap exists in what and how it is possible to fabricate continuous and random-structured piezoelectric devices with large sensitive area and high degrees of alignment and uniformity raised in current piezoelectric polymer processing technologies.

### SUMMARY

Objects and advantages of the invention will be set forth in part in the following description, or may be obvious from the description, or may be learned through practice of the invention.

Methods are generally provided for forming a piezoelectric device. In one embodiment, the method comprises: electrically poling and printing the piezoelectric device from a polymeric filament simultaneously. The polymeric filament can comprise a polyvinylidene fluoride polymer (e.g., a β phase polyvinylidene fluoride polymer, such as formed by simultaneously stretching and electric poling an electrically inactive a phase polyvinylidene fluoride polymer).

In particular embodiments, the polymeric filament is formed from a polymeric material passed through an extrusion nozzle while the nozzle is heated at a temperature (e.g., about 185° C. to about 275 OC, such as about 200° C. to about 250 OC) that is greater than the glass transition temperature of the polymeric material.

Electrically poling can be achieved by applying an electric field between the nozzle of the extruder and the printing surface of about 1.0 MV/m to about 3.0 MV/m (e.g., about 1.5 MV/m to about 2.5 MV/m).

In certain embodiments, the polymeric filament has a diameter of about 200 μm to about 1 mm (e.g, about 250 μm to about 750 μm).

When desired, the method can be achieved by mechanically, thermally, and/or electrically poling and printing the piezoelectric device from a polymeric filament simultaneously.

Other features and aspects of the present invention are discussed in greater detail below.

### BRIEF DESCRIPTION OF THE DRAWINGS

A full and enabling disclosure of the present invention, including the best mode thereof to one skilled in the art, is set forth more particularly in the remainder of the specification, which includes reference to the accompanying figures, in which:

FIG. 1A shows a configuration of a phase crystalline of PVDF polymer, with F (fluoride), C (carbon), and H (hydrogen).

FIG. 1B shows a configuration of β phase crystalline of PVDF polymer, with F (fluoride), C (carbon), and H (hydrogen).

FIG. 2 shows an exemplary schematic diagram of AM-based electric poling system.

FIG. 3A shows the experimental setup according to the example.

FIG. 3B shows the polymer extruding result according to the example.

FIG. 4 shows FTIR measurement results according to the example.

FIG. 5 shows the method of printed PVDF device according to the example.

FIG. 6 shows current ouputs with respect to applied electric field strength according to the example.

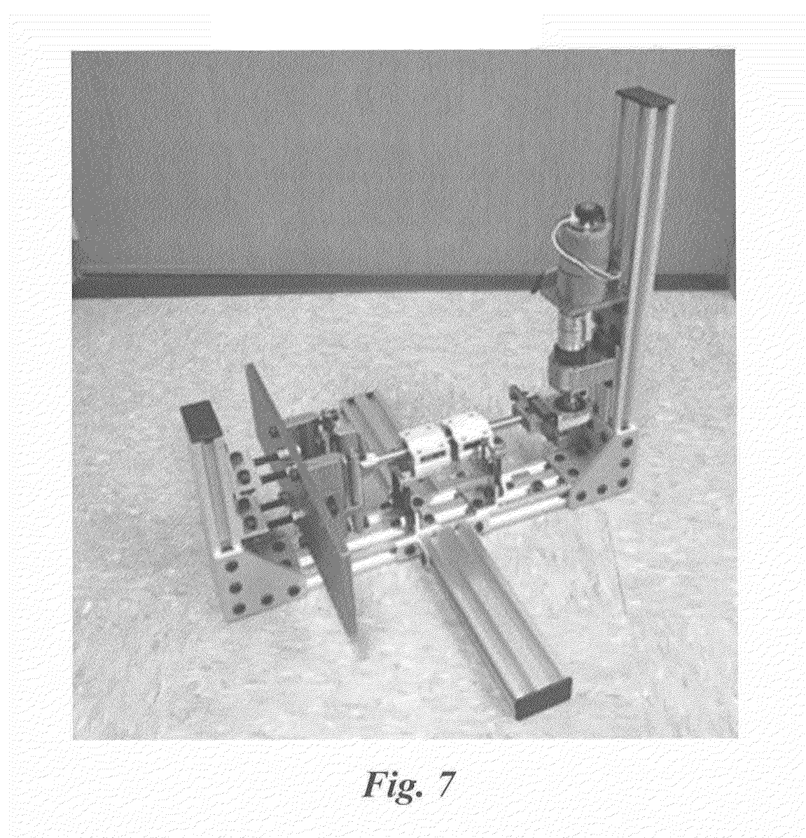

FIG. 7 shows a fatigue test machine for polymers according to the example.

FIGS. 8A and 8B shows preliminary material property test results of ABS under different layer thickness and feed conditions, with FIG. 8A showing elastic modulus and FIG. 8B showing strength.

FIG. 9A shows an exemplary schematic diagram of a printing mechanism of a general FDM process

FIG. 9B shows an exemplary schematic diagram of a printing mechanism of a filament feeding process.

FIG. 9C shows an exemplary schematic diagram of a printing mechanism of a and granules feeding process.

FIG. 10 shows the basic principle of an exemplary piezoelectric device formed according to one embodiment.

FIG. 11A shows results of static analyses; FIG. 11B shows results of dynamic analysis; and FIG. 11C shows results of harmonic analyses: L=30 mm, t=1mm, w=5 mm, F=0.1N.

FIG. 12 shows a diagram of an exemplary charge amplifier circuit utilizing a piezoelectric sensor.

FIG. 13 shows a Bode diagram of circuit transfer function, H(ω).

FIG. 14 shows a schematic diagram of one exemplary proposed printing process of the piezoelectric PVDF device with the electric poling and mechanical stretching process in EPAM process.

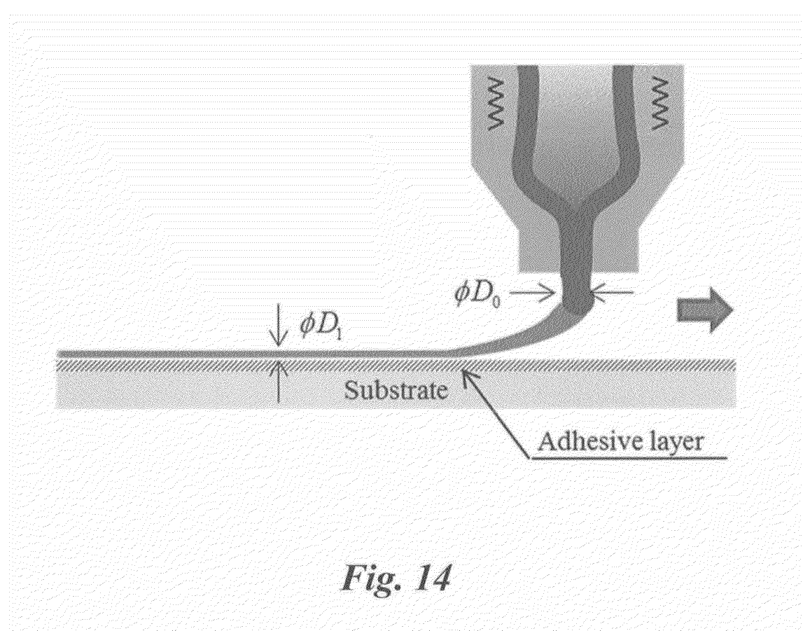

### DEFINITIONS

Chemical elements are discussed in the present disclosure using their common chemical abbreviation, such as commonly found on a periodic table of elements. For example, hydrogen is represented by its common chemical abbreviation H; helium is represented by its common chemical abbreviation He; and so forth.

“Piezoelectricity” is the electric charge that accumulates in certain solid materials such as crystal and certain ceramics in response to applied mechanical stress. A key characteristic of these materials is the utilization of the converse piezoelectric effect to actuate the structure in addition to the direct effect to sense structural deformation. When a piezoelectric polymer is subjected to a mechanical load, positive and negative charges generate on the material surface. This ability to generate charge on the material can convert mechanical energy into electrical energy and vice versa. Linear piezoelectric constitutive relations derived from thermodynamic principles, couple linear elastic relations with linear dielectric relations through the piezoelectric devices. Under small field conditions, the constitutive relations for a piezoelectric material can be expressed as

$$\begin{matrix}{D}_{i} = {e}_{ij}^{σ} {E}_{j} + {d}_{im}^{d} {σ}_{m} & ( 1 ) \\ {ɛ}_{k} = {d}_{ik}^{c} {E}_{j} + {s}_{km}^{E} {σ}_{m} & ( 2 ) \\ [ \begin{matrix}D \\ ɛ\end{matrix} ] = [ \begin{matrix}{e}^{σ} & {d}^{d} \\ {d}^{c} & {s}^{E}\end{matrix} ] [ \begin{matrix}E \\ σ\end{matrix} ] & ( 3 )\end{matrix}$$

Equation (1) is the sensor equation, and Equation (2) is the actuator equation. The sensor is exposed to a stress filed, and generates a charge in response, which is measured by using a charge amplifier circuit. While actuator applications are based on the converse piezoelectric effect and it is bonded to a structure and an external electric field is applied and a strain field is induced as a result. Equation (1) and (2) can be combined into Equation (3) in a matrix form. Vector D of size (3×1) is the electric displacement (Coulomb/m²), ∈ is the strain vector (6×1), E is the applied electric field vector (3×1) (Volt/m) and Γₘ is the stress vector (6×1) (N/m²). The piezoelectric constants are the dielectric permittivity eᵢⱼ^{σ} of size (3×3) (Farad/m), the piezoelectric coefficients dᵢₘ^{d} (3×6) and d_{c}^{jk} (6×3), and the elastic compliance sₖₘ^{E} of size (6×6) (m²/N). The piezoelectric coefficient dⱼₖ^{c}(m/Volt) defines strain per unit field at constant stress and dᵢₘ^{d} (Coulomb/N) defines electric displacement per unit stress at constant electric field. The superscripts c and d have been added to differentiate between the converse and direct piezoelectric effects, but these coefficients are numerically equal in practice. The superscripts a and E indicate that the quantity is measured at constant stress and constant electric field, respectively.

As used herein, the term “polymer” generally includes, but is not limited to, homopolymers; copolymers, such as, for example, block, graft, random and alternating copolymers; and terpolymers; and blends and modifications thereof. Furthermore, unless otherwise specifically limited, the term “polymer” shall include all possible geometrical configurations of the material. These configurations include, but are not limited to isotactic, syndiotactic, and random symmetries.

The glass transition temperature (T_{g}) may be determined by dynamic mechanical analysis (DMA) in accordance with ASTM E1640-09. A Q800 instrument from TA Instruments may be used. The experimental runs may be executed in tension/tension geometry, in a temperature sweep mode in the range from −120° C. to 150° C. with a heating rate of 3° C./min. The strain amplitude frequency may be kept constant (2 Hz) during the test. Three (3) independent samples may be tested to get an average glass transition temperature, which is defined by the peak value of the tan δ curve, wherein tan δ is defined as the ratio of the loss modulus to the storage modulus (tan δ=E″/E′).

As used herein, the prefix “nano” refers to the nanometer scale (e.g., from about 1 nm to about 999 nm). For example, fibers having an average diameter on the nanometer scale (e.g., from about 1 nm to about 999 nm) are referred to as “nanofibers.” Fibers having an average diameter of greater than 1,000 nm (i.e., 1 μm) are generally referred to as “microfibers”, since the micrometer scale generally involves those materials having an average size of greater than 1 μm.

### DETAILED DESCRIPTION

Reference now will be made to the embodiments of the invention, one or more examples of which are set forth below. Each example is provided by way of an explanation of the invention, not as a limitation of the invention. In fact, it will be apparent to those skilled in the art that various modifications and variations can be made in the invention without departing from the scope or spirit of the invention. For instance, features illustrated or described as one embodiment can be used on another embodiment to yield still a further embodiment. Thus, it is intended that the present invention cover such modifications and variations as come within the scope of the appended claims and their equivalents. It is to be understood by one of ordinary skill in the art that the present discussion is a description of exemplary embodiments only, and is not intended as limiting the broader aspects of the present invention, which broader aspects are embodied exemplary constructions.

A completely transformative manufacturing process is generally provided that integrates stretching and electric poling processes into a single Additive Manufacturing (AM) process to produce piezoelectric PVDF devices. In one embodiment, a new AM process is provided to directly and continuously print piezoelectric devices from polyvinylidene fluoride (PVDF) polymeric filament rods under a strong electric field. This process, called ‘electric poling-assisted additive manufacturing’ (EPAM) combines AM and electric poling processes and is able to fabricate free-form shape piezoelectric devices continuously. In this process, the PVDF polymer dipoles remain well aligned and uniform over a large area in a single design, production and fabrication step. During EPAM process, molten PVDF polymer is simultaneously mechanically stresses in-situ by the leading nozzle and electrically poled by applying high electric field under high temperature.

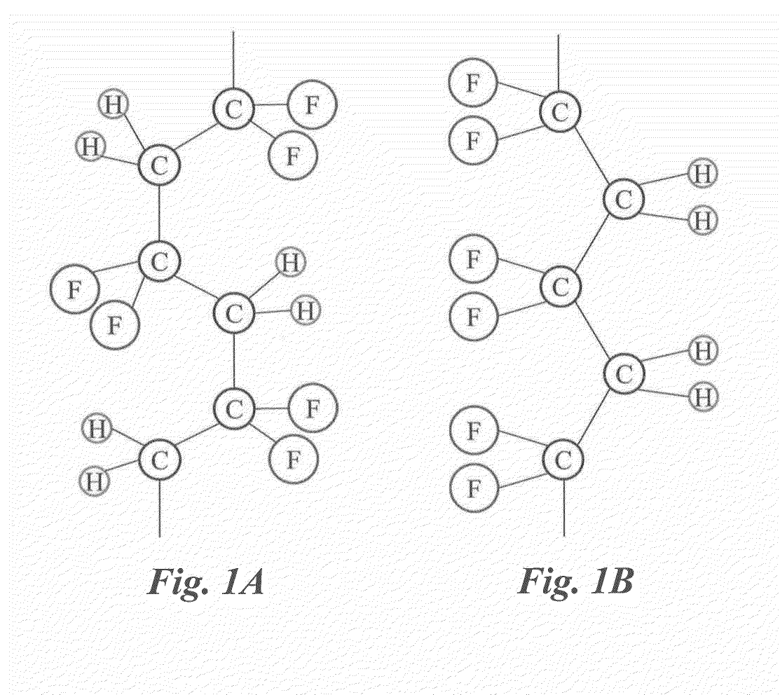

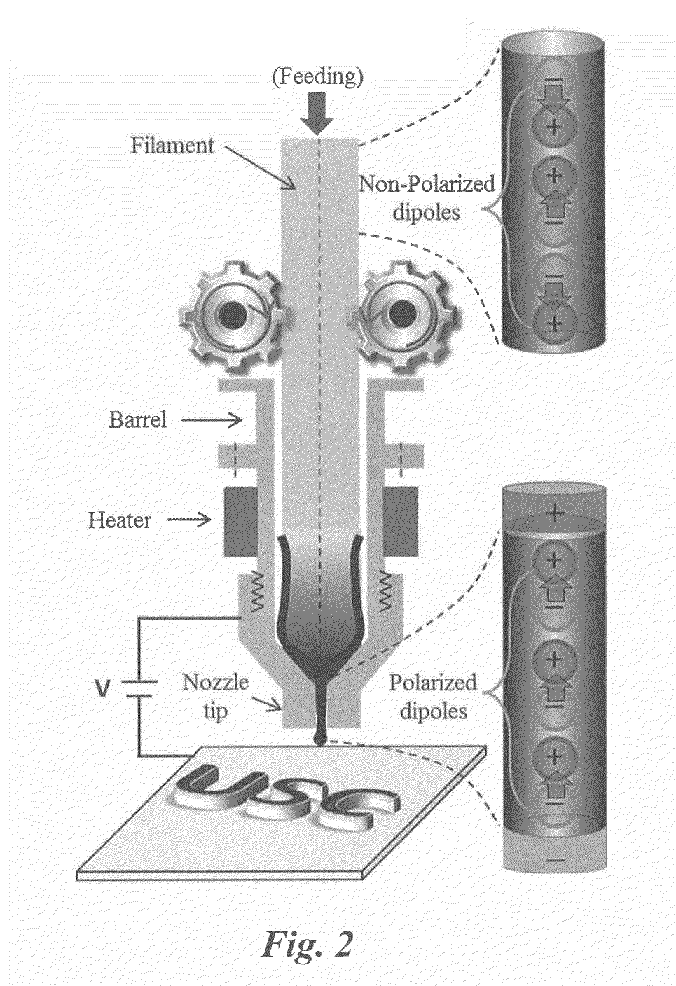

PVDF exists in α, β, γ and δ crystalline phases depending on the chain conformation. The relative quantity of each is dependent on the thermal mechanical and electrical processing conditions used to produce PVDF film or fiber. The phase of PVDF is primarily responsible for its piezoelectric properties because the piezoelectricity is based upon dipole orientation within the crystalline phase. As seen in FIGS. 1A and 1B, respectively, the non-polar α phase has random orientation of dipole moments while the polar β phase has all the dipole moments pointing to the same direction in all-trans zigzag conformation, such that β phase is mostly responsible for the piezoelectric property of the polymer. In general, piezoelectric PVDF polymers are traditionally manufactured by using mechanical stretching, contact poling, corona poling or electro-spinning process in order to allow for dipole alignment of the polymer.

There are four well-known polymer processing processes to create β-phase PVDF. These are electrospinning, mechanical stretching, contact poling, and corona poling. Stretching a PVDF material by either uniaxial or biaxial stress provides molecular chain alignment (conversion to β-phase from α-phase), and subsequently applying a strong electric field causes dipole alignment along the electric field (contact poling). Corona poling ionizes air molecules above the material through the use of a corona needle. In order to allow polymer chain to align and reorganize, PVDF is held at high temperature during stretching and poling. Electrospining is a unique technique able to produce PVDF fibers and continuous filaments from PVDF solutions in the presence of an electrical field.

Additive Manufacturing technology is ideal for making prototypes during the early development phases of a product-significantly reducing the cost and time required for production development and market launch. The strengths of AM lie in those areas where conventional manufacturing reaches its limitations. The technology is of interest where a new approach to design and manufacturing is required so as to come up with solutions. What is more, AM allows for highly complex structures which can still be extremely light and stable.

There are a large number of AM processes available such as fused deposition modeling (FDM), selective laser sintering (SLS), selective laser melting (SLM) and Stereolithography (SLA). An exemplary FDM process can begin with a software process that processes a stereolithography file mathematically slicing and orienting the model for the build process. The component is produced by extruding small beads of thermoplastic material to form layers as the material hardens immediately after extrusion from the nozzle. A polymeric filament is unwound from a coil and supplies material to an extrusion nozzle while the nozzle is heated over the glass transition temperature of polymer to melt the material. At the end, the component is built from the bottom up, one layer at a time. In a general FDM process, an extruder motor feeds a highly non-reactive pure PVDF polymeric filament to an extruder that is heated above PVDF melting temperature, about 160° C. to about 180° C. Heating the PVDF polymer filament causes it to melt down and the molten polymer flows through the nozzle tip of extruder when the extruding motor is on.

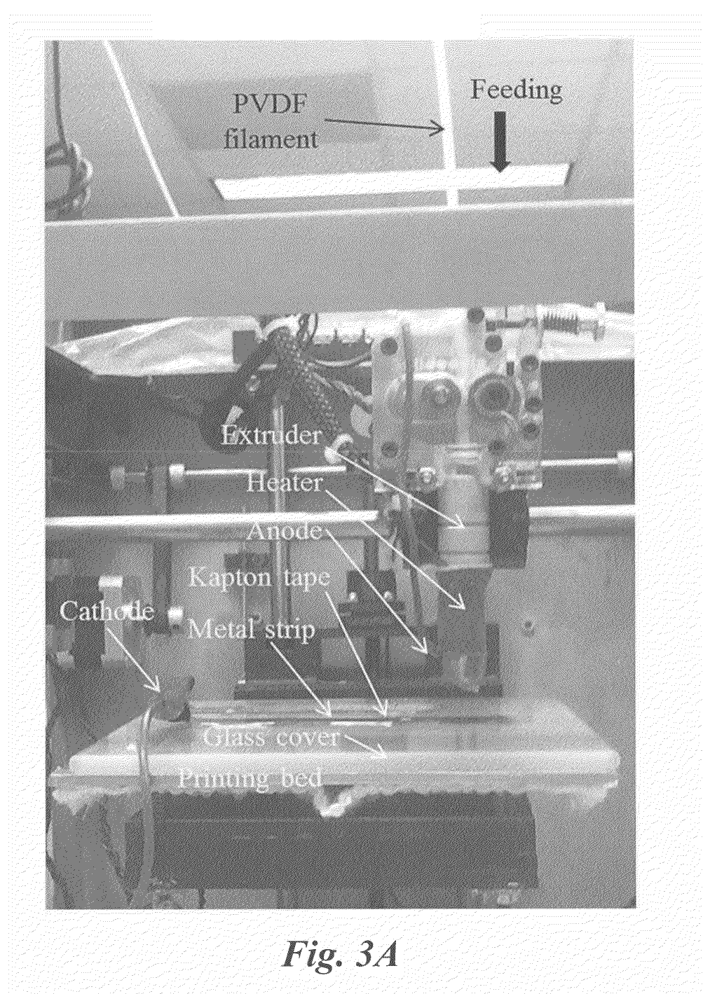

Referring now to FIG. 2, an AM-based polymer poling process for piezoelectric device fabrication is shown based on the filament feeding process, which allows poling and printing the piezoelectric device from the polymeric filament simultaneously. As the poling process involves chains at the interface as well as the rotation of the dipoles in the crystallites, significant changes in the thermal, electric, chemical and mechanical properties of PVDF polymer will appear. In order to obtain β phase PVDF, electrically inactive a phase PVDF is first prepared by a stretching and electric poling process at the same time while printing the structures made of PVDF polymer. The directions of polarization of individual crystallites in PVDF polymer filament are randomly distributed, whereas the polarization directions become biased towards the direction of the applied electric field after stretching and electric poling processes. Thus, PVDF polymer thermally molten in the extruder can be realigned to crystallize in β phase structure with dipoles of all chains under stretching and electric poling processes, and piezoelectric PVDF polymer structures can be printed by FDM machine. One of the models aiming to explain the poling process involves rotation by 180° of each polymer chain along its own axis and another model involves also a rotation by 60°.

As referred to Table 1, the process can be compared advantageously with electrospinning process most commonly used in piezoelectric polymer processing in terms of cost, processing issues raised in polymer processing, product capability, and productivity. This new manufacturing process enables us to not only produce a continuous piezoelectric PVDF polymer fiber with β phase conformation but also allow us to provide design flexibility for precision sensing applications at ultra-low cost.

In summary, novel piezoelectric polymer processing technology is generally provided to fabricate multifunctional 3D structured piezoelectric devices with high volumetric densities and high degrees of alignment and uniformity by fusing AM process and electric poling process into a completely new process. AM is essential to realize the concept of “on-demand” manufacturing for improving output volume and quality control and minimizing the cost and time. Generally, 3D structured devices can be printed from PVDF filament, granules and powder by using AM process, Fused Deposition Modeling (FDM), while applying a high electric field through PVDF polymer.

### Example 1

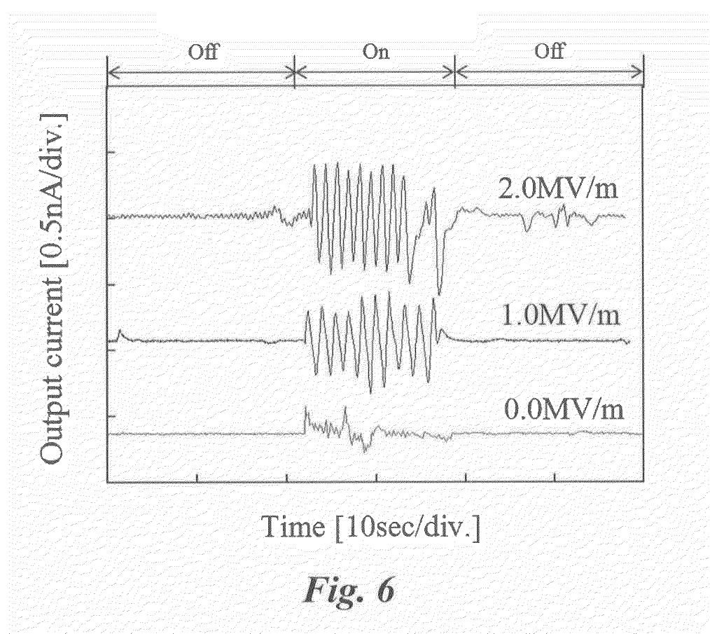

We recently investigated a completely transformative manufacturing process that integrates stretching and polymer poling processes into a single AM process. The new manufacturing process enables us to not only produce a continuous piezoelectric PVDF polymer fiber with β-phase conformation but also allows us to construct 3D structures made of piezoelectric PVDF polymer for precision sensing applications at ultra-low cost. We modified an FDM machine to apply a high voltage between a nozzle tip of extruder and printing bed while printing. In a general FDM process, an extruder motor feeds a highly non-reactive pure PVDF polymeric filament to an extruder that is heated up to 230° C. (PVDF melting temperature, 160° C.). The PVDF polymer filament melts down and the molten polymer flows through the nozzle tip of extruder when the extruding motor is on. Here a strong electric field, 2 MV/m, allows for dipole alignment of PVDF polymer fiber poled mechanically between the nozzle tip and bed plate. Finally, we can produce a continuous piezoelectric PVDF fiber with a diameter of 500 μm. The diameter of fiber can be adjusted by designing the geometry of nozzle tip hole and controlling the poling feedrate. We tested the performance of piezoelectric device fabricated by the proposed manufacturing process. Both ends of piezoelectric device were fixed with high conductive Cu adhesive tape as electrodes and the current was measured while pushing down and pulling up the poled polymer. PVDF fibers with a diameter of 500 μm and length of 30 mm were fabricated under two electric field conditions: 0 MV/m and 2 MV/m. As presented in FIG. 5, PVDF fiber fabricated under 2 MV/m electric field condition produced the current ±0.4 nA with respect to displacement direction. While, PVDF fiber fabricated under no electric field was not sensitive to the displacement. As a result, our invention can improve piezoelectric polymer devices and make a new market for piezoelectric 3D structured sensor and actuator applications.

### Example 2

A novel manufacturing process was utilized for polymer-based piezoelectric device fabrication by integrating additive manufacturing and electric poling processes. The system was constructed to print piezoelectric devices directly from filament type of polyvinylidene fluoride (PVDF) polymer while applying high electric field between printing nozzle tip and bed in the fused deposition model machine: 0 MV/m, 1.0 MV/m and 2.0 MV/m. The piezoelectric samples were successfully fabricated by the proposed manufacturing process and the phase transition of each sample was identified by using the Fourier transform infrared spectroscope (FTIR). As a result, it was found simple mechanical stretching only through the printing process cannot produce dipole alignment of the PVDF polymer, and the higher electric field is applied, the more the device is piezoelectric and the sharper the peak is at polar β crystalline wavenumber of PVDF polymer. In addition, those results showed a good agreement with those of FTIR. This process is expected to replace the current polymer-based piezoelectric device fabrication processes and create piezoelectric three-dimensional structured devices for sensing, energy harvesting and actuation applications.

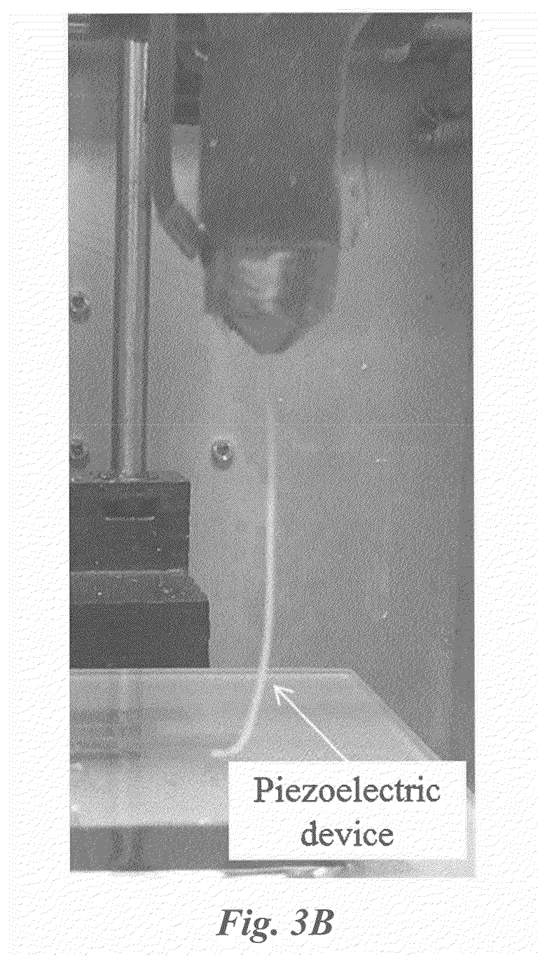

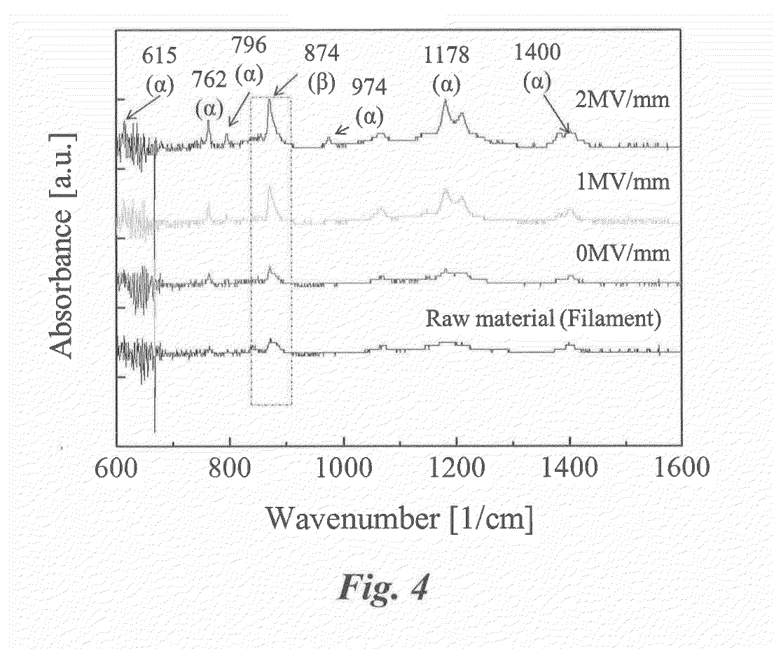

A completely transformative manufacturing process was experimentally investigated by integrating mechanical stretching and electric poling processes into a single AM process. A FDM machine was modified to apply a high electric field between a nozzle tip of extruder and printing surface while printing as presented in FIG. 3 because a strong electric field allows for dipole alignment of PVDF polymer. PVDF filament was inserted into an extruder along the feeding direction. The extruder was constructed of stepper motor-driven filament feeding mechanism, heater, thermocouple and nozzle tip. The extruder pushed the filament down, and the filament molten by heater was printed through the nozzle tip with a diameter of 0.4 mm. Temperature was feedback controlled. High voltage was applied between the nozzle tip as an anode and the metal strip as a cathode. Printing bed was supposed to be heated up by the internal heater. Glass cover was placed for electric insulation. Kapton tape (0.2 mm thickness) as printing top surface was applied on the metal strip. The experiment conditions were tabulated in Table 2.

To investigate the effect on piezoelectric characteristics of the PVDF polymer with respect to the electric poling condition, PVDF devices, 100 mm long, 1.0 mm wide and 0.3 mm thick, were printed under four different conditions of electric field: 0.0 MV/m, 1.0 MV/m, 2.0 MV/m and 3.0 MV/m. The geometry of the printed PVDF device can be adjusted by designing the geometry of nozzle tip hole and controlling the poling feedrate. The printing gap between the nozzle tip and printing top surface was set to 0.3 mm. In a poling condition, 3.0 MV/m, the corona discharging was found. It resulted in burning Kapton tape-applied surface and difficulty to maintain the electric field constant, which is against the principle in the electric poling process that the static electric field is assumed to be applied. It was considered that the electric field higher than 3.0 MV/m cannot be applied in the proposed process due to the corona discharging effect.

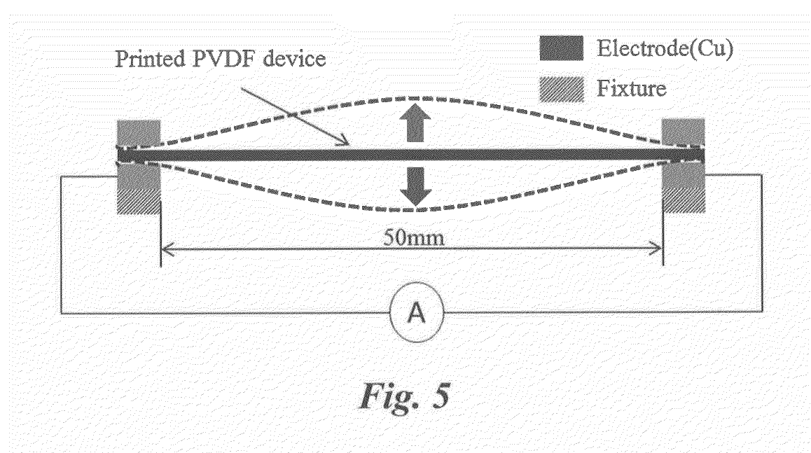

The PVDF phase with respect to electric poling conditions was investigated. Here the Fourier Transform Infrared Spectroscopy (FTIR, Galaxy series FTIR 5000) was used to obtain an infrared spectrum of absorption of PVDF samples fabricated by AM process under different electric poling conditions. First, the filament as printing material was measured as a reference, and then, three printed PVDF samples were measured as presented in FIG. 4. It was found that samples that the electric field was not applied show nearly similar results with those of PVDF filament. While, new peaks were found in the samples that the electric filed was applied. In addition, existing peaks became sharp at certain wavenumbers. In the samples fabricated under high electric field, the peaks could clearly be seen at the wavenumber, 874, whose crystalline is β phase, and the wavenumber 1178, α phase. And it was found that those peaks show the tendency to being sharper as the strength of electric field increases. PVDF samples fabricated by AM process under different electric poling conditions were tested as presented in FIG. 5. PVDF device was self-suspended between two fixtures, 50 mm distance away, and both ends of piezoelectric device were securely fixed with high conductive Cu adhesive tape as electrodes. The current was measured while pushing down and pulling up the printed PVDF devices. It can be seen that PVDF device fabricated under higher electric field condition, 2.0 MV/m, produces the higher current, ±0.37 nA with respect to displacement direction when the sample is subjected to cyclic loading, “On” and does not produce the current when it is stationary. Similar measurement results were found in other samples. The current output of the sample printed under the electric field condition, 1.0 MV/m, was measured ±0.25 nA when it was in motion. While, the sample fabricated under no electric field was not less sensitive than others to the displacement even though small current signal was seen.

These results indicate that simple mechanical stretching only through the printing process cannot produce significant dipole alignment of the PVDF polymer, and the higher electric field is applied, the more the device is piezoelectric. Moreover these results showed a good agreement with those of FTIR measurement results as presented in FIG. 4.

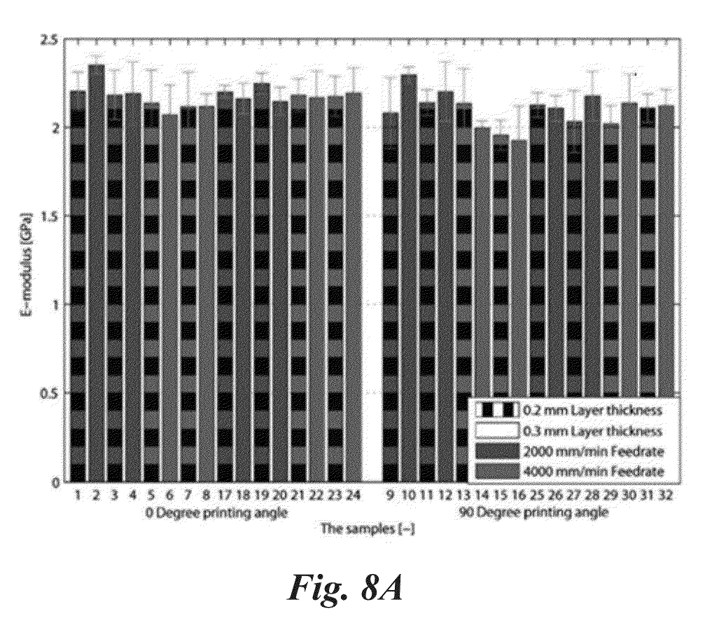

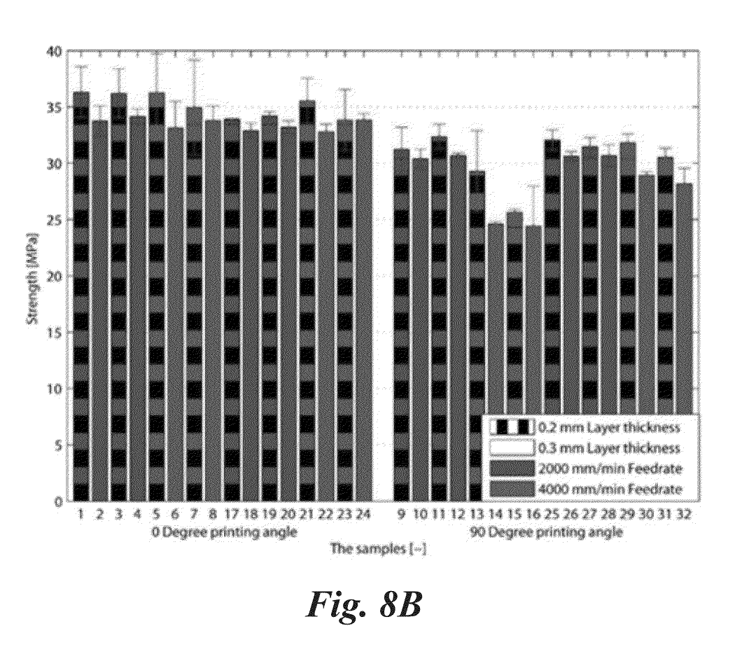

A fatigue test machine was designed and built to measure the fatigue properties of polymer materials produced by AM processes. The test machine was custom built for the low loads that polymer materials can endure (FIG. 7). It was designed in accordance with ASTM D7774-12, the standard test method for Flexural Fatigue Properties of Plastics. The standard requires certain levels of precision and accuracy in the programmed displacement and deflection measuring systems along with providing standardized geometry for the loading system and test sample. Using this test machine we will be able to develop fatigue S-N curves and Paris curves for each type of AM polymer material. This will allow us to develop a Design of Experiment and obtain data regarding the effect of build parameters on material fatigue properties. This type of data is not readily available from OEMs. A preliminary investigation was done of the relationship between printing parameters and material performance. Printing parameters can be classified into two groups: printer parameters (slicing algorithm, part modeling, and material selection) and printing processing parameters (printing temperature, size, feedrate, and orientation). Poorly selected printing parameters result in poor surface quality, voids and non-uniform structures. Design of Experiments (DOE) was used to evaluate the effect of the layer thickness, print speed, and build on the material properties. The results are shown in FIG. 8 demonstrate that the speed, print orientation, and layer thickness can have a significant impact on the modulus of elasticity and ultimate strength. In addition, the fatigue behavior will also depend on these and other quality parameters.

### CONCLUSION

The completely transformative AM-based novel process was proposed to produce polymer-based piezoelectric devices by integrating stretching and polymer poling processes into an AM process. The piezoelectric samples were successfully printed by the proposed manufacturing process under different electric field conditions, and the phase transition of each sample was characterized by using the FTIR. From the measurement results, it can be known that the higher peak is found at polar β crystalline wavenumber of PVDF polymer and the high current is generated as strength of applying electric field increases, which indicates that the proposed process can provide dipole alignment of the polymer molecular chain alignment and transforms the polymer from a phase to β phase by applying a strong electric field while printing simultaneously. As a result, it was confirmed that this process is more useful and efficient than general piezoelectric polymer processing processes, mechanical stretching, contact poling, corona poling or electro-spinning process. This piezoelectric polymer processing process is expected to replace the current polymer-based piezoelectric device fabrication processes and create piezoelectric three-dimensional structured devices with continuous and large effective area for sensing, energy harvesting and actuation applications.

### First Exemplary Embodiment

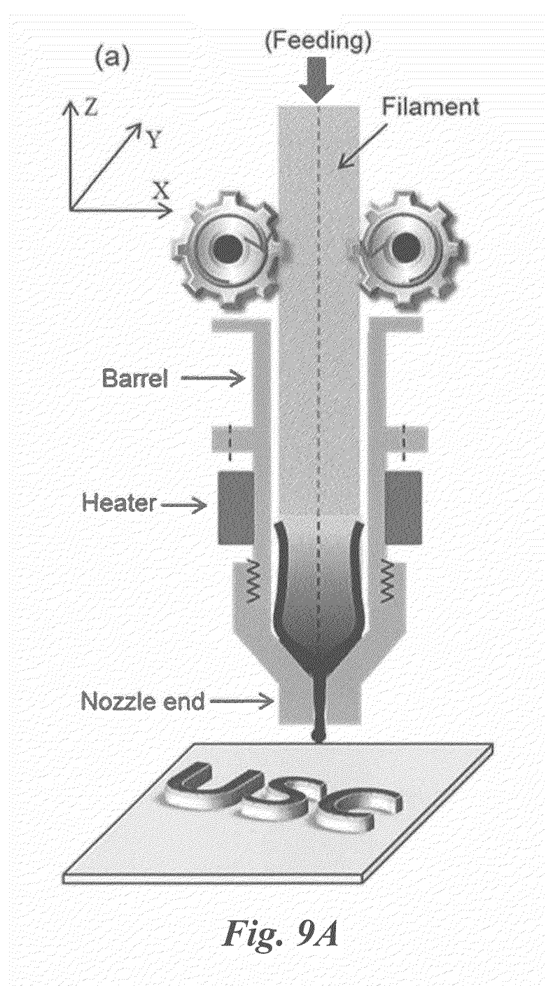

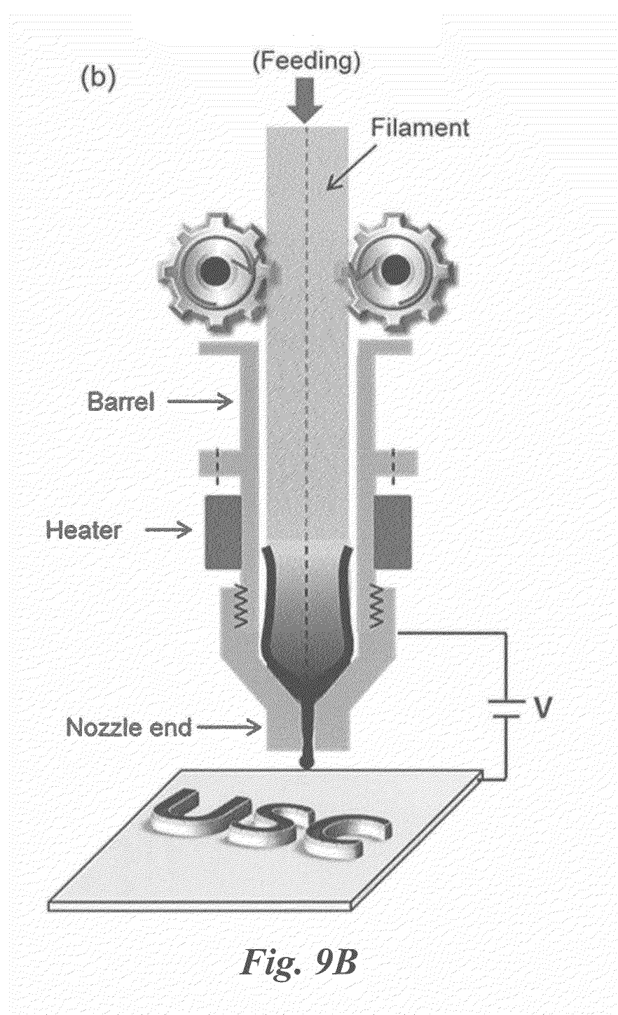

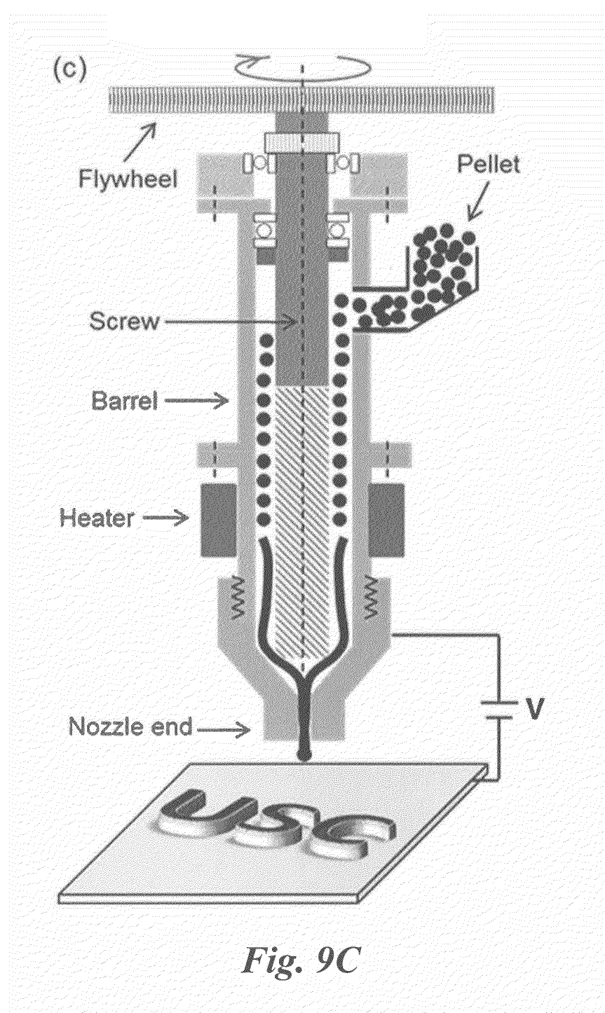

In this first exemplary embodiment, two AM-based polymer poling processes for piezoelectric 3D structured device fabrication can be used: filament feeding process and granules feeding process (FIG. 9). The former is the process to pole and print the piezoelectric device from the polymeric filament simultaneously and the latter is from granules. Each feeding mechanism of extruding systems can be properly designed based on printing performance. The FDM process can be taken into account only for experiment because FDM machine is suitable for our purpose. FDM is an additive manufacturing technology commonly used for modeling, prototyping, and production applications. As seen in FIG. 9, FDM begins with a software process that processes a stereolithography file mathematically slicing and orienting the model for the build process. The component can be produced by extruding small beads of thermoplastic material to form layers as the material hardens immediately after extrusion from the nozzle. A polymeric filament is unwound from a coil and supplies material to an extrusion nozzle while the nozzle is heated over the glass transition temperature of polymer to melt the material. At the end, the component is built from the bottom up, one layer at a time.

For filament feeding system, the FDM machine (Solidoodle) commercially-available can be modified by applying a strong electric field between a nozzle tip of extruder and printing bed with high voltage power supply (Pullman LS2000) as presented in FIG. 9. Here, piezoelectric polymer filament with a diameter of 3.0 mm commercially available can be used. The piezoelectric polymer processing parameters can be determined such as electric field poling strength, extruding temperature, extruding feedrate, mechanical poling feedrate of the extruder head and the bed temperature based on Design Of Experiment (DOE). At the same time, the level of crystallinity of piezoelectric polymer printed by AM machine can be tested to quantify dipole alignment by using Atomic Force Microscope (AFM), Raman spectroscope and X-ray Energy Dispersive Spectroscope (EDS) at USC. Moreover, a piezoelectric device can be produced from piezoelectric granules or power for granules feeding system instead of filament to investigate the performance difference between piezoelectric devices fabricated by using proposed two different piezoelectric polymer processing methods. Granules or power type of piezoelectric polymer is preferred for mass production because it is much cheaper than filament type and extremely cheaper than solution type. There is little work in granules or power-based piezoelectric device production. The electrospinning process, which is the most commonly used in PVDF processing, and our processes are summarized in detail in Table 1. It can be seen that our processes are suitable to not only create 3D structured piezoelectric devices, but also achieve the cost innovation. We will test two piezoelectric polymer-based AM processes and optimize all processing parameters for high piezoelectric device performance.

Electromechanical model of piezoelectric polymer device can be used to estimate its thermal/mechanical/electrical performance characteristics in advance. Piezoelectric polymer device can be characterized by Finite Element Method (FEM) and Molecular Dynamic (MD) simulation. Three FEM analyses can then be performed by using PTC Creo and Ansys software regarding 3D structured piezoelectric device fabricated by AM machine: static analysis to estimate deflection, dynamic analysis to estimate displacement, velocity, acceleration with respect to temporal and spatial frequency, and harmonic analysis to estimate the steady-state response of piezoelectric device to input loads varying harmonically with time.

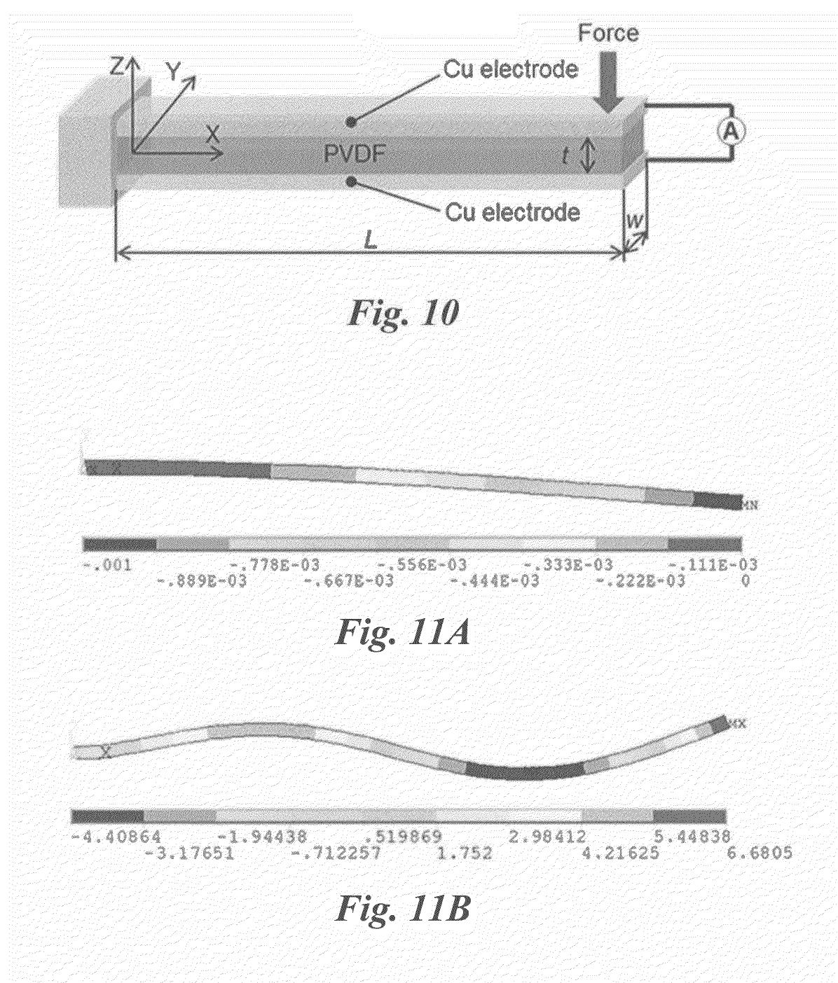

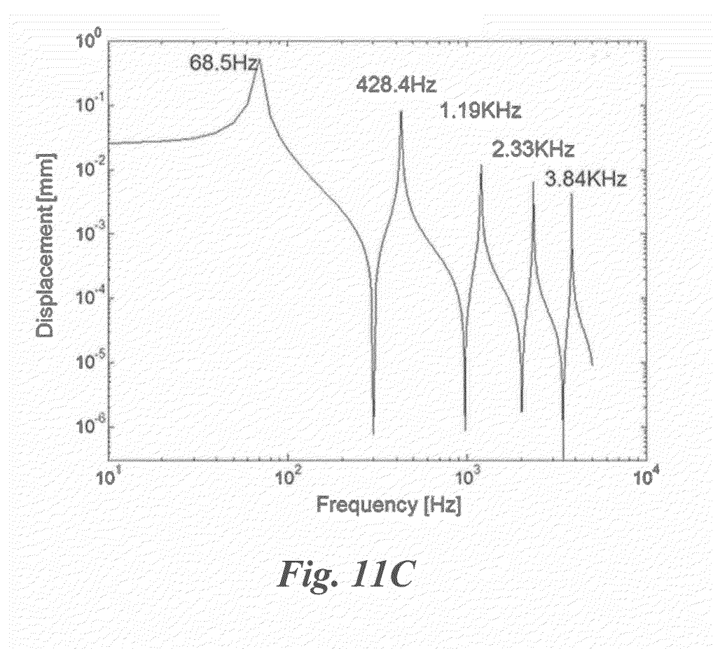

As a first approach, a simple cantilever beam can be printed (FIG. 10), and all electrical and mechanical properties can be identified by comparing FEM-based theoretical results with experimental results. The theory of Bernoulli-Euler beam can be applied to model piezoelectric polymer cantilever beam. The governing equation of motion of the Bernoulli-Euler beam is expressed as

$$\frac{{\partial }^{4} z}{\partial {x}^{4}} + \frac{ρ wt}{EI} \frac{{\partial }^{2} z}{\partial {t}^{2}} = F ( t )$$

where E is Young's modulus, I moment of inertia, ρ density, w width of beam and t thickness of beam, F(t) force with a function of time. From the geometrical dimensions and material properties of the cantilever beam, the all electrical and mechanical properties of piezoelectric device will be identified as a result of FEM analysis in FIG. 11. And then, a 3D structured piezoelectric device can be designed and printed based on known physical properties of piezoelectric polymer.

### Second Exemplary Embodiment

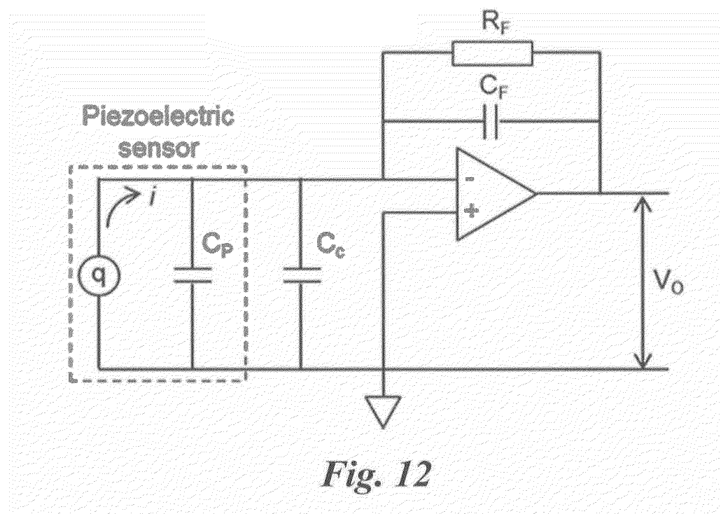

The circuit design and signal processing technique for piezoelectric device with high signal-to-noise ratio (SNR) can be used to understand fundamental principles in piezoelectric devices and characterize its performance in terms of sensitivity and response characteristics. In this task, an optimized electric circuit can be designed by modeling piezoelectric device itself and construct signal processing implementations in a LabView environment to achieve high SNR. The output of the piezoelectric device has to be passed through some signal conditioning electronics in order to accurately measure the voltage being developed by the device because of high output impedance. The primary purpose of the signal conditioning system is to provide a signal with low output impedance while simultaneously presenting a very high input impedance to the piezoelectric device. The signal conditioning circuit is shown in FIG. 12. The piezoelectric device can be modeled as a charge generator in parallel with a capacitance Cₚ equal to the capacitance of the device. The cables which carry the signal to the charge amplifier, collectively act as a capacitance C_{c} in parallel with the device. The charge amplifier has several advantages. First, the charge generated by the device is transferred onto the feedback capacitance Cₚ. Once the value of Cₚ is known, the calibration factor is fixed, irrespective of the capacitance of the device. Second, the value of time constant, which is given by multiplication of Rₚ and Cₚ can be selected to give the required dynamic frequency range. It is to be noted, however, that there is always some finite leakage resistance in the piezoelectric material, which causes the generated charge to leak off. Therefore, though the time constant of the circuit can be made very large to enable operation at very low frequency, it is not possible to determine a pure static condition. This basic physical limitation exists for all kinds of devices utilizing the piezoelectric effect. Third, the effect of the lead wire capacitance C_{c} presented often for any physical measurement system is eliminated. This has the important consequence that there are no errors introduced in the measurement by the lead wires. Considering only the charge generated by strain along the x-direction, the current I can be expressed in Equation (5):

i=\dot{q}=S_{q}\dot{∈}ₓ (5)

Assuming ideal operational amplifier characteristics, the governing differential equation of the circuit can be derived in Equation (6), which, for harmonic excitation, has the solution.

$${V}_{O} + \frac{{V}_{O}}{{R}_{F} {C}_{F}} = - \frac{\text{?} \text{?}}{{C}_{F}} \\ \text{?} \text{indicates text missing or illegible when filed} \qquad ( 6 )$$

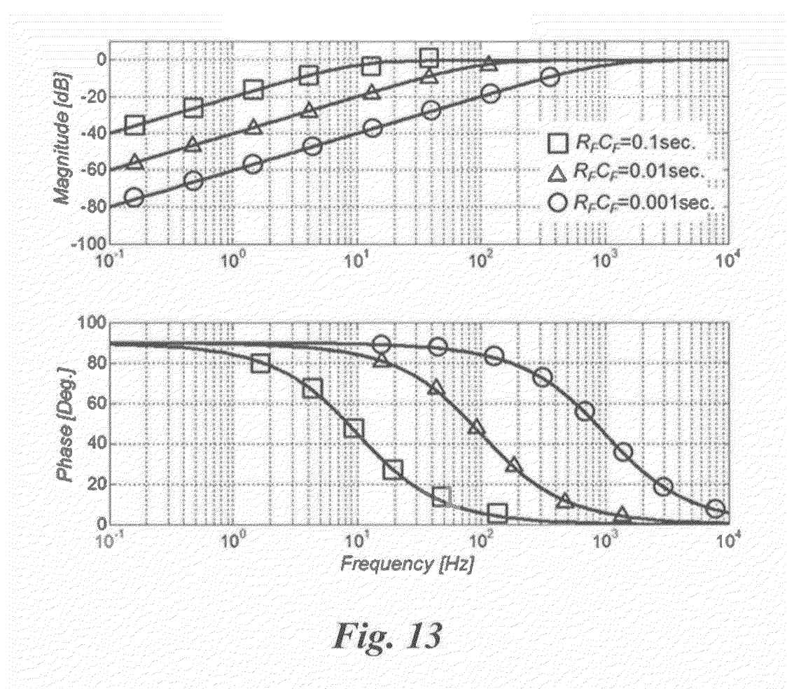

which the quantities with a bar represent their magnitudes, and ω is the frequency of operation in Equation (7). The magnitude and phase of the gain H(ω) are plotted for different time constant values, while setting Rᵥ=10MΩ in FIG. 13. It can be seen that this represents a high pass filter characteristics, with a time constant, Rₚ Cₚ.

$${\overline{V}}_{O} = - ( \frac{j ω {R}_{F} {C}_{F}}{1 + j ω {R}_{F} {C}_{F}} ) \frac{\text{?} \text{?}}{{C}_{F}} = - H ( ω ) \text{?} \text{?} \\ \text{?} \text{indicates text missing or illegible when filed} \qquad ( 7 )$$

### Third Exemplary Embodiment

The eletromechanical modeling, fatigue characterization, morphological analysis and crystallinity characterization, test and 3D geometric design of piezoelectric polymer devices can be used to answer fundamental questions about mechanicallelectrical properties, the failure mechanism and optimization problem in 3D structured piezoelectric polymer device. In this embodiment, a piezoelectric polymer device can be characterized in two approaches: traditional and morphological/crystallographic characterization.

First, a piezoelectric polymer device can be designed to show that AM can be used to for 3D structured piezoelectric device applications, and tested by creating a complete precision testing facility. The device can be calibrated using displacement sensors and microbending tester and measure the piezoelectric characteristics to determine linearity, hysteresis, repeatability, precision, and noise using displacement sensor. In addition, the complete device can be tested in terms of fatigue and reliability characteristics as well as its dynamic temporal and spectral performance by using lab-built fatigue test machine. And then, the fatigue fracture mechanics model can be built based on frequency and temperature effect. When piezoelectric device is subjected to repeated cyclic loading and unloading, it degrades its performance due to the crack growth and structural deformation induced by thermal accumulation.

It is well-known that the effect of temperature is to increase the crack growth rate independent of the frequency, and that frequency has the opposite effect. For a given flaw, the deterministic relation (Paris law) between the crack propagation rate per cycle, da/dN, and the change in stress intensity factor, Kₗ, can be established in Equation (8), where C is the coefficient, Y the geometric factor depending on the crack and the position in the structure, a the crack depth, σ local tensile stresses. We will find each fatigue parameter by testing under each test temperature. At the end, the fatigue models for piezoelectric device can be built by using not only empirically the stress versus fatigue life based on S/N curves as well as Paris law curves but also theoretically Finite Element Analysis (FEA) with PTC Creo or Ansys software at the University of South Carolina (Columbia, S.C.).

$$\frac{d a}{d N} = C Δ {K}_{I} , {K}_{I} = σ Y \sqrt{π a} \qquad ( 8 )$$

Second, the level of crystallinity of the piezoelectric device can be tested by using Atomic Force Microscope (AFM), Raman spectroscope and X-ray Energy Dispersive Spectroscope (EDS). Crystallinity is a key thermodynamic parameter affecting the mechanical, chemical and thermal properties of semi-crystalline polymers. Without crystallinity or defined morphology, piezoelectric polymer would not exhibit any piezoelectric properties since it could not sustain a net dipole. Thus, the changes of the level of crystallinity of the piezoelectric device can be tested in view of the performance degradation due to the fatigue limits and build the deterministic relation between the level of crystallinity and fatigue limits for reliability characterization

TABLE 1
Comparison of PVDF polymer poling processes.

| Technology | Electrospinning process | AM-based poling process |
|---|---|---|
| PVDF material type | Solution (expensive) | Filament (cheap) |
| PVDF product type | Few mm fiber | No limit in length |
| | Limited to 1D structure | Design flexibility (3D) |
| Productivity | Slow | Fast |
| | Small area fabrication | Large area fabrication |
| Processing issues | Sensitive to temp./ | Less sensitive to |
| | humidity | environment |

TABLE 2
Piezoelectric polymer processing conditions.

| Process parameters | Conditions |
|---|---|
| Material | PVDF polymer filament (ø3 mm) |
| Extruder temp. [° C.] | 230 |
| Bed temp. [° C.] | 100 |
| Printing feed [mm/min] | 300 |
| Electric field [MV/m] | 0.0/1.0/2.0/3.0 |

These and other modifications and variations to the present invention may be practiced by those of ordinary skill in the art, without departing from the spirit and scope of the present invention, which is more particularly set forth in the appended claims. In addition, it should be understood the aspects of the various embodiments may be interchanged both in whole or in part. Furthermore, those of ordinary skill in the art will appreciate that the foregoing description is by way of example only, and is not intended to limit the invention so further described in the appended claims.

What is claimed:

1. A method of forming a piezoelectric device, the method comprising:
electrically poling and printing the piezoelectric device from a polymeric filament simultaneously, wherein the polymeric filament comprises a polyvinylidene fluoride polymer.

2. The method of claim 1, wherein the piezoelectric device is a 3D device.

3. The method of claim 1, where the piezoelectric device is built one-layer at a time from the bottom up.

4. The method of any claim 1, wherein the piezoelectric device comprises β phase polyvinylidene fluoride polymer.

5. The method of claim 4, wherein the R phase polyvinylidene fluoride polymer is formed by: simultaneously stretching and electric poling an electrically inactive a phase polyvinylidene fluoride polymer.

6. The method of claim 1, wherein the polymeric filament is formed from a polymeric material passed through an extrusion nozzle while the nozzle is heated at a temperature that is greater than the glass transition temperature of the polymeric material.

7. The method of claim 6, wherein the nozzle has a temperature during printing in the range of about 185° C. to about 275° C.

8. The method of claim 6, wherein the nozzle has a temperature during printing in the range of about 200° C. to about 250° C.

9. The method of claim 6, wherein the nozzle has a temperature during printing in the range of about 225° C. to about 235° C.

10. The method of claim 6, wherein electrically poling is achieved by applying an electric field between the nozzle of the extruder and the printing surface of about 1.0 MV/m to about 3.0 MV/m.

11. The method of claim 6, wherein electrically poling is achieved by applying an electric field between the nozzle of the extruder and the printing surface of about 1.5 MV/m to about 2.5 MV/m.

12. The method of any preceding claim, wherein the polymeric filament has a diameter of about 200 μm to about 1 mm.

13. The method of claim 1, wherein the polymeric filament has a diameter of about 250 μm to about 750 μm.

14. The method of claim 1, comprising:
mechanically and electrically poling and printing the piezoelectric device from a polymeric filament simultaneously.

15. The method of claim 1, comprising:
mechanically, thermally, and electrically poling and printing the piezoelectric device from a polymeric filament simultaneously.
